(19) United States
(12) Patent Application Publication
(10) Pub. No.: US 2007/0194840 A1
(43) Pub. Date: Aug. 23, 2007

(54) Method and circuit for adjusting an RC element

(75) Inventors: Lutze Dathe, Dresden (DE); Henry Drescher, Radebeul (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/702,101

(22) Filed: Feb. 5, 2007

(30) Foreign Application Priority Data
Feb. 3, 2006 (DE) DE102006005778.3

(51) Int. Cl. H03K 5/00

(52) U.S. Cl. 327/552

(57) ABSTRACT

A method for adjusting an RC element with a capacitive element with adjustable capacitance, in particular a capacitor, and/or a resistive element with adjustable resistance, in particular an ohmic resistance, is provided. Multiple adjustment cycles are performed, wherein each adjustment cycle sets a standard value for the capacitance of the capacitive element and/or for the resistance of the resistive element, charges the capacitive element for a predefinable charging time, compares a charging voltage to which the capacitive element has been charged during the charging time with a reference voltage. A comparison result is obtained that indicates whether the charging voltage is larger than the reference voltage or vice versa. In addition, the standard value for the capacitance and/or the resistance and/or the charging time for a subsequent adjustment cycle is selected as a function of the comparison result of at least one preceding adjustment cycle.

This nonprovisional application claims priority under 35 U.S.C. § 119(a) on German Patent Application No. DE 102006005778, which was filed in Germany on Feb. 3, 2006, and which is herein incorporated by reference.

### BACKGROUND OF THE INVENTION

1. Field of the Invention

The present invention relates to a method for adjusting an RC element with a capacitive element with an adjustable capacitance, in particular a capacitor, and/or a resistive element with adjustable resistance, in particular an ohmic resistance. In addition, the invention concerns a circuit for adjusting such an RC element.

2. Description of the Background Art

From DE 101 56 027 A1, which corresponds to U.S. Pat. No. 6,628,163, is known a method for adjusting an active filter having an RC combination that determines a time constant of a filter. The prior art method provides for the connection of the RC combination to a signal generator that generates a square-wave signal as a function of the actual component values of the RC combination. The square-wave signal is connected to the enable input of a counter to determine the number of clock cycles of a clock signal, likewise connected to the counter, that correspond to the pulse duration of the square-wave signal. The number of clock cycles is proportional to the time constant defined by the RC combination.

A disadvantage of this method and the corresponding circuit is, in particular, the limitation of the resolution in the measurement of the pulse duration of the square-wave signal resulting from a clock frequency of the clock signal. In other words, in order to achieve a sufficiently high resolution for measuring and representing the pulse duration of the square-wave signal, a clock signal with a correspondingly high frequency must be provided. This in turn requires the use of a counter with sufficient data width so that an appropriate evaluation of the pulse duration can be carried out.

Moreover, particularly with a high-frequency signal, the mapping of a data word of the counter representing the pulse duration to a data word controlling the capacitor field by means of the decoder specified in DE 101 56 027 A1 is extremely complicated, especially when a lookup table is used, since the lookup table must likewise have a corresponding size.

A conventional remedy for achieving adequate precision while not requiring the use of a high-frequency clock signal is to provide sufficiently large component values for the RC combination, i.e. to increase the pulse duration of the square-wave signal produced by the signal generator, and thus the measurement time period. This has a disadvantageous effect on the area required, especially for the capacitive components of the RC combination, adversely affecting the integratability of the circuit.

### SUMMARY OF THE INVENTION

It is therefore an object of the present invention to provide a method and circuit of the aforementioned type in such a manner as to provide more precise adjustment of an RC element and improved integratability.

This object is attained according to the invention in a method and a circuit in that multiple adjustment cycles are performed, wherein each adjustment cycle can include the following steps: a) setting a standard value for the capacitance of the capacitive element and/or the resistance of the resistive element; b) charging the capacitive element for a predefinable charging time; and c) comparing a charging voltage to which the capacitive element has been charged during the charging time with a predefinable reference voltage. Whereby a comparison result is obtained that indicates whether the charging voltage is larger than the reference voltage or vice versa, and the standard value for the capacitance and/or the resistance and/or the charging time for a subsequent adjustment cycle is selected as a function of the comparison result of at least one preceding adjustment cycle.

The inventive method using multiple adjustment cycles eliminates the need, as in the prior art method, to measure the pulse duration of a signal that is produced specifically for the adjustment process as a function of the capacitive element that is to be adjusted.

Rather, by means of a change, e.g. a stepwise change, in the standard value for the capacitance of the capacitive element between successive adjustment cycles, the inventive method makes it possible to determine the optimal standard value for the capacitance of the capacitive element, where the charge voltage present after the charging time is in the region of the predefinable reference voltage. The predefinable reference voltage is selected such that it corresponds to the charging voltage that a fully adjusted capacitive element exhibits when it is charged with a specific charging time and charging method. In this context, a fully adjusted capacitive element is defined as a capacitive element whose actual capacitance matches the desired capacitance that is to be achieved.

Attainment of the optimal standard value for the capacitance can be detected in a simple manner by a change in the comparison result between two successive adjustment cycles. For example, a first number of adjustment cycles with a first number of standard values for the capacitance of the capacitive element may all produce the comparison result that the charging voltage is smaller than the reference voltage. In these cases the corresponding values chosen for the capacitance are all too large in comparison with the optimal standard value, because the reference voltage is not reached during the charging time.

Once a different comparison result, indicating that the charging voltage is larger than the reference voltage, is achieved for the first time after another adjustment cycle, it can be concluded that the optimal standard value for the capacitance lies between the standard value presently selected and the standard value selected for the previous adjustment cycle.

Accordingly, the localization of the optimal standard value for the capacitance by the inventive method requires only the repeated execution of a relatively simple adjustment cycle and a simple evaluation in the form of a comparison of two voltage values. The significantly more complicated measurement of the pulse duration of a reference signal and a correspondingly complex control system, or the use of a counter component to determine a variable time duration, which are necessary in the prior art method, are eliminated.

Furthermore, the desired precision in the approximation of the standard value for the capacitance can take place solely through the appropriate selection of the standard values to be set for the individual adjustment cycles, for example. The use of a high-frequency clock signal is not necessary. Moreover, the precision of the adjustment using the inventive method can be influenced by the selection of the adjustment algorithm without, for example, the provision of larger component values for the capacitive element that results in poorer integratability of the prior art circuits.

In general, an embodiment of the inventive method accordingly provides that the standard value for the capacitance for the next adjustment cycle can be increased/decreased if the charging voltage in the preceding adjustment cycle was larger/smaller than the reference voltage.

Alternatively or in addition to the change in the standard value for the capacitance, it is also possible for a standard value for the adjustable resistive element to be changed in a comparable manner, in order to change the time constant of the RC element correspondingly. In general, an RC element requiring adjustment can thus have both tunable and non-tunable capacitive and resistive components, although at least one tunable resistive or capacitive element should be present.

Alternatively to a change in the standard value for the capacitance and/or the resistance, a change in the charging time for a subsequent adjustment cycle can also take place according to the invention. In this way, for a given value range of the adjustable capacitance of the capacitive element, for example, it is possible for the step of comparing the charging voltage with the reference voltage to simulate a capacitive element with a different capacitance than the capacitance actually set. For example, when setting the largest possible standard value for the capacitance, it is possible to simulate the charging process for a capacitive element with twice the capacitance by halving the charging time, assuming a constant charging current, and so forth. Accordingly, at least the determination of the actual capacitance value of the capacitive element can take place within a larger value range than is possible without a variation in the charging time. Similar considerations apply for an expansion of a given value range for the resistance of the resistive element.

Accordingly, in another exemplary embodiment, provision is made for the charging time for the next adjustment cycle to be increased/decreased if the charging voltage in the preceding adjustment cycle was larger/smaller than the reference voltage.

In another embodiment, provision is made for the capacitive element to be charged by a charging circuit with a constant current. As a result of the linear relationship that exists here between the capacitor voltage and the charging time, the time variation in the charging voltage has a constant value, so that comparable precision in comparing the charging voltage with the reference voltage can be achieved even for different charging times. Because of the linear relationship between charging time and capacitance of a capacitor charged by means of a constant charging current, this variant method is especially easy to combine with the change in charging time described above.

Even though charging of the capacitive element with a constant current represents the preferred version, in another embodiment, it is also possible for the capacitive element to be charged by a charging circuit through a dropping resistor and a reference voltage source, wherein the dropping resistor is preferably composed at least partially of the resistive element. To this end, the charging circuit has an appropriately designed reference resistor as a dropping resistor, which can be connected in series with the capacitive element, and the resultant series circuit is charged by the reference voltage source. In this version, the charging time is selected such that it is less than or equal to a time constant that is determined by the reference resistor and the standard value for the capacitance of the capacitive element, in order to avoid the asymptotic region of the time behavior of the charging voltage and the associated disadvantages of a reduced sensitivity of the charging voltage with respect to the charging time.

In another embodiment, provision is made that a maximum or minimum adjustable capacitance of the capacitive element and/or a maximum or minimum adjustable resistance of the resistive element can be chosen as the standard value for a first adjustment cycle. In this way, a systematic search of the entire value range of the capacitance of the capacitive element or the resistance of the resistive element for the optimal standard value is possible.

According to another embodiment, the standard value, which can in general be the standard value for the capacitance and/or the standard value of the resistance, can be changed by a predefinable step size between each set of successive adjustment cycles. A change of, for example, the capacitance with a constant step size is possible for capacitive elements that are composed of a number of individual capacitors of equal capacitance, which can be connected in parallel to one another under the control of, e.g., a suitable switch matrix in order to form the capacitance of the capacitive element through their resulting equivalent capacitance.

Other arrangements of capacitors that permit stepwise implementation of different equivalent capacitances are also possible. For example, different capacitors having capacitances with, e.g., binary graduations, can be arranged so as to be connectible in parallel with one another, in order to permit a binary graduation of standard values for the capacitance of the capacitive element. Analogous structures for implementing different resistance values can be constructed in a comparable manner.

Such a change in the standard value for the capacitance with variable step size permits an especially precise adjustment of the capacitive element. For example, in a first pass the inventive method can be carried out with a comparatively large step size for the standard value in order to determine the interval between the standard values in which the optimal standard value is located. Subsequently, the inventive method can be carried out in a second pass with a comparatively small step size for the standard value in order to further reduce the interval to be examined.

In another embodiment, provision is made for the step size to be chosen as a function of the number of adjustment cycles already carried out. In this context, large step sizes for the standard value can be used at the beginning of the inventive method, and as the number of adjustment cycles increases the step size correspondingly decreases, while the precision of the method increases at the same time.

Another embodiment includes, for example, the following steps: maintaining the present value of the step size for the next adjustment cycle if the comparison result of the current adjustment cycle is identical to the comparison result of the preceding adjustment cycle; reducing, in particular halving, the present step size for the next adjustment cycle if the comparison result of the current adjustment cycle is not identical to the comparison result of the preceding adjustment cycle; and/or ending the adjustment as soon as the step size chosen for the next adjustment cycle drops below a predefinable threshold value.

Namely, if the comparison result of the current adjustment cycle is identical to the comparison result of the preceding adjustment cycle, it can be assumed that the change in the standard value for the capacitance has accomplished a further approach to the desired value, and has not caused the desired value to be exceeded. Accordingly, a subsequent adjustment cycle can be carried out with the same step size.

However, if the comparison result of the current adjustment cycle is not identical to the comparison result of the preceding adjustment cycle, it can be assumed that the change in the standard value for the capacitance has caused the desired value to be exceeded, so that a further approach of the standard value for the capacitance to the desired value in a subsequent adjustment cycle will require, firstly, a change in the standard value in the direction opposite to the previous direction. Secondly, the step size is simultaneously reduced in accordance with the invention in order to achieve a better approach to the desired value. This advantageously results in an asymptotic approach of the standard value to the desired value, and the precision of this variation of the method is limited only by the smallest possible adjustable step size of the capacitance.

Alternatively or in addition to the variation of the standard value for the capacitance, a corresponding variation of the standard value for the resistance is also possible in the above-described embodiment of the inventive method.

In another embodiment, the capacitive element can be discharged after the comparison step. This ensures that the same conditions are always present at each charging step, namely an absolutely discharged capacitive element. Alternatively or in addition, the discharging of the capacitive element can also take place before the step of charging or setting of the standard value.

In another embodiment, a charging circuit can be used to charge the capacitive element is disconnected from the capacitive element before the comparison step, so that the charging voltage does not change during the comparison.

A circuit for adjusting an RC element can include a capacitive element, in particular a capacitor, and/or a resistive element having an adjustable resistance, in particular an ohmic resistance, and can have the following elements: a charging circuit for charging the capacitive element that can be connected at least to a first terminal of the capacitive element; a comparator circuit having a first input, a second input and an output, wherein the first input is supplied with a reference potential corresponding to a reference voltage, and wherein the second input can be connected to the first terminal of the capacitive element; and a control device that is configured to control the circuit according to the inventive adjustment method.

In contrast to prior art adjustment circuits, the inventive circuit very advantageously requires no counter circuit for determining a variable time duration as is required, for example, by prior art circuits for determining a pulse duration of a reference signal. The inventive circuit may determine the charging time, which can be defined as an integer multiple of the period duration of a clock signal with a known and above all constant frequency, for example. This eliminates the need to provide a high-frequency clock signal whose frequency must be chosen to be high enough that a pulse duration of a reference signal to be measured occupies a large enough number of periods of the high-frequency clock signal so that a sufficient measurement precision can be achieved in the measurement of the pulse duration.

According to another embodiment of the invention, the control device can have a state machine and/or can be designed as a state machine.

In another embodiment, a discharging circuit for discharging the capacitive element can be provided that can be connected to at least one terminal of the capacitive element. In an especially simple variant, the discharging circuit can have a switch that connects the terminal of the capacitive element to a reference potential such as, e.g., ground potential. Like the connection of the charging circuit to the capacitive element by suitable switching means, the discharging circuit can also be controllable by the control device.

Another very embodiment of includes a clock generator circuit for producing a clock signal. A control signal that defines the charging time can be directly derived from this clock signal, as already described.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic representation a circuit according to an embodiment of the present invention;

FIG. 2 illustrates a detail view of the capacitive element depicted in FIG. 1;

FIG. 3a is a flow diagram of an embodiment of the inventive adjustment method; and

FIG. 3b is another flow diagram of an embodiment of the inventive adjustment method.

### DETAILED DESCRIPTION

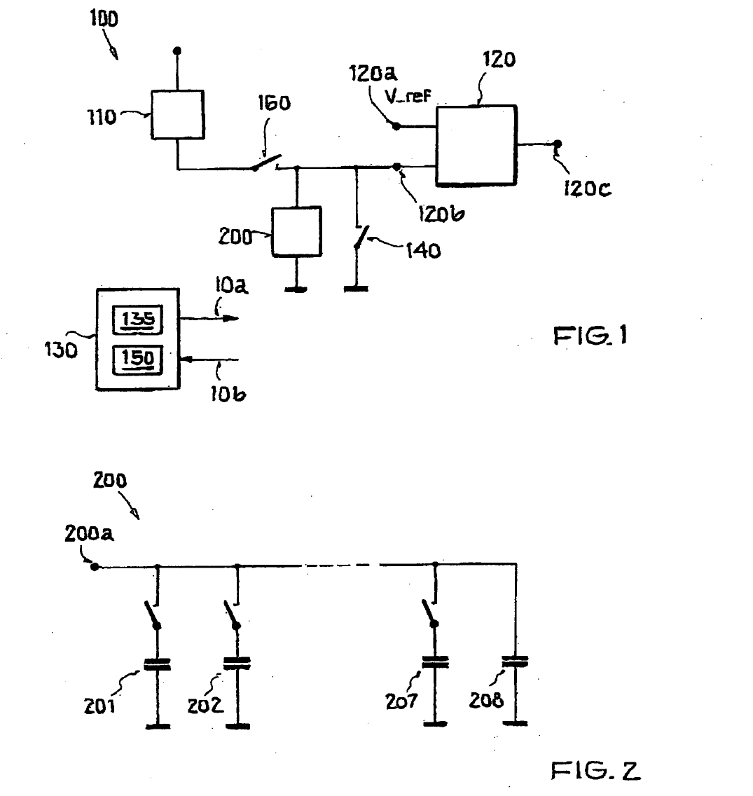

Shown schematically in FIG. 1 is an embodiment of the inventive circuit 100 for adjustment of an RC element. In addition to the capacitive element 200 shown, which is composed, for example, of a capacitor, the RC element also has at least one ohmic resistance (not shown). In the present example, adjustment of the RC element is accomplished by adjustment of its capacitive element 200. The RC element requiring adjustment may be, for example, an RC element that is used in filter circuits in order to achieve a time constant τ=RC of the filter circuit. In order to adjust the capacitance of the capacitor 200, or a time constant depending thereon, to a desired value, the inventive adjustment circuit 100 described below is temporarily connected to the capacitor 200. Such a connection can be made, for example, through appropriate switches—not shown—through which the capacitor 200 can be reconnected to the filter circuit after the adjustment method, for example.

The adjustment circuit 100 has a charging circuit 110 for charging the capacitor 200, said charging circuit being connectable to a first terminal of the capacitor 200 through a switch 160. As can be seen from FIG. 1, a second terminal of the capacitor 200 is connected to the ground potential.

The adjustment circuit 100 also has a discharge circuit 140, which in the present example is designed as a simple switch and is provided for discharging the capacitor 200. To discharge the capacitor 200, the switch 140 is closed, and the switch 140 remains open while the capacitor 200 is charged, e.g., through the charging circuit 110.

The inventive adjustment circuit 100 additionally has a comparator circuit 120, which has two inputs 120a, 120b, and an output 120c. The comparator circuit 120 compares two potentials or voltages with one another, and outputs an appropriate logic signal at its output 120c as a function of the comparison in a known manner.

In order to control the adjustment circuit 100, moreover, a control device 130 is provided, which receives at its inputs (not shown in detail) input signals 10b representing operating information of the adjustment circuit 100, and which outputs control signals 10a at its outputs. For example, the state of the discharging circuit 140 or of the switch 160, which connects the charging circuit 110 to the capacitor 200, is controlled by the control device 130. Evaluation of the logic signal output at the output 120c of the comparator circuit 120 is likewise performed by the control device 130.

The control device 130 advantageously has a state machine 135 for sequence control. In order to make available a time base for the adjustment process described below, the control device 130 can also include a clock generator circuit 150. Alternatively, the control device 130 can also be supplied with a clock signal from another circuit component (not shown).

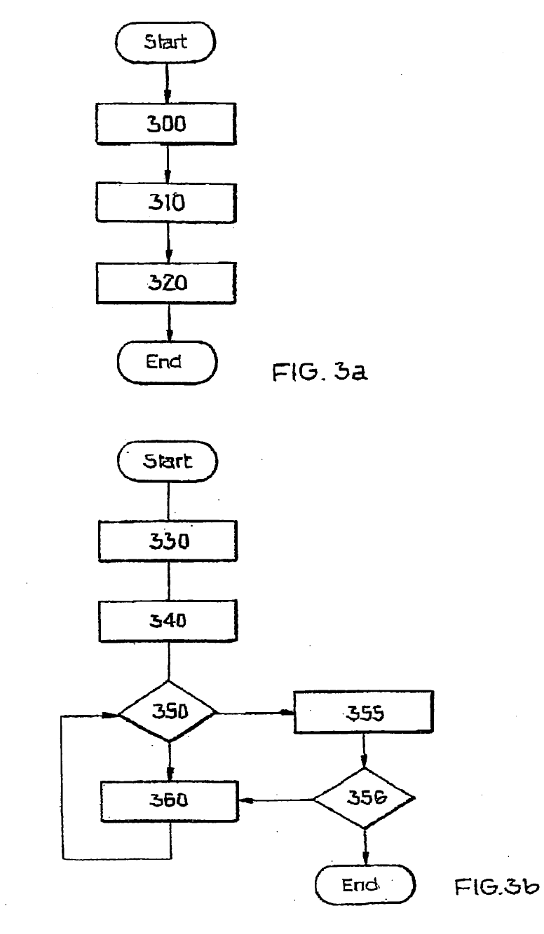

In order to carry out the adjustment of the capacitor 200 to a predefined desired value, the inventive adjustment method is carried out, which is described in detail below on the basis of the flow diagrams in FIGS. 3a, 3b.

The adjustment process includes multiple adjustment cycles, wherein each adjustment cycle has essentially three steps. In the first step 300 of each adjustment cycle (FIG. 3a), a standard value for the capacitance of the capacitor 200 is first set. In the present example, the capacitor is set as shown in FIG. 2 by a parallel connection of multiple individual capacitors 201, 202, . . . , 207, 208, and the capacitance can be set through appropriate driving of the switches (not shown in detail in FIG. 2) associated with the individual capacitors.

As is evident from FIG. 2, only the capacitor 208 is permanently connected to the terminal 200a, and thus by means of its capacitance simultaneously constitutes the minimum possible equivalent capacitance of the capacitor 200. Accordingly, the maximum possible capacitance of the capacitor 200 results when all additional individual capacitors 201, 202, . . . , 207 are connected in parallel to one another by closing the switches associated with them.

The capacitance values of the individual capacitors 201, . . . , 208 can be distributed in any desired manner per se. Especially simple versions provide, for example, for the individual capacitors 201, . . . , 208 to each have the same capacitance. An embodiment provides for the individual capacitors 201, . . . , 208 to have capacitance values with binary graduations, by which means a larger maximum value range for the equivalent capacitance is achievable. The binary graduation of the capacitance values of the individual capacitors 201, . . . , 208 can be accomplished in that, for example, adjacent capacitors 201, 202 have capacitances differing by the factor two.

Setting of the standard value for the capacitance per step 300 from FIG. 3a is accomplished by the control device 130 (FIG. 1), which drives the switches of the individual capacitors 201, . . . , 208 (FIG. 2) through appropriate output signals 10a. For example, the minimum possible capacitance is set for the first adjustment cycle, which is to say all switches depicted in FIG. 2 are open.

In the second step 310 (FIG. 3a) of the inventive adjustment cycle, the capacitor 200 is charged for a predefinable charging time. This is accomplished by closing the switch 160 (FIG. 1), thus connecting the charging circuit 110 with the first terminal 200a of the capacitor 200 shown in detail in FIG. 2. The charging circuit 110 advantageously has a constant current source (not shown in detail), so that the capacitor 200 is charged with a constant charging current in step 310, and the time variation in the charging voltage appearing at the capacitor 200 is likewise constant.

The constant current source of the charging circuit 110 can have, for example, a voltage reference and a reference resistance, which generate the charging current of desired current amplitude. By means of a current mirror, the charging current can be provided in a known way at the output of the charging circuit 110 connected to the capacitor 200.

Prior to the charging step (310), it is necessary to ensure by briefly closing the switch 140 that the capacitor 200 is fully discharged, to keep from distorting a subsequent evaluation of the charging process.

The charging time is determined in the control device 130, and can be selected as, for example, an integer multiple of a period duration of the clock signal provided by the clock generator circuit 150. After the charging time has elapsed, the charging circuit 110 is disconnected from the capacitor 200 by opening of the switch 160. In this state, the charging voltage to which the capacitor 200 was charged during the charging period, is present at the second input 120b of the comparator circuit 120.

A reference potential corresponding to a reference voltage V_ref is supplied to the first input 120a of the comparator circuit 120. The reference voltage V_ref is selected such that it corresponds to the charging voltage that a fully adjusted capacitor 200 exhibits at the end of the charging time. In other words, it is evident from the agreement between the actual charging voltage of the capacitor 200 and the reference voltage V_ref that the standard value selected for the adjustment cycle for the capacitance of the capacitor 200 corresponds to the desired target capacitance. Accordingly, the agreement of the actual charging voltage of the capacitor 200 with the reference voltage V_ref characterizes the adjusted state.

In step 320 (FIG. 3a), the actual charging voltage of the capacitor 200 is now compared with the reference voltage V_ref, and a corresponding comparison result is obtained at the output 120c of the comparator circuit 120. Among other things, this result is evaluated by the control device 130 in order to control any further adjustment cycles.

According to the invention, the standard value for the capacitance 200 for a subsequent adjustment cycle is chosen as a function of the comparison result of at least one preceding adjustment cycle. For example, it is determined during the evaluation of the first adjustment cycle in its step 320 that the charging voltage is greater than the reference voltage V_ref. In this case, it is concluded that the standard value chosen for the capacitance of the capacitor 200 in the first adjustment cycle was too small.

Accordingly, a standard value for the capacitance of the capacitor 200 is set for the next adjustment cycle in step 300 that is larger than the previously set capacitance value, which, as already described, was the minimum possible capacitance of the capacitor 200. A suitable increase in the capacitance is accomplished in the present example by switching in one or more of the individual capacitors 201, . . . , 207 (FIG. 2) to the permanently connected capacitor 208.

Then the above-described steps 310, 320 are carried out for the second adjustment cycle as well. The standard value for the capacitance can be further increased for each of the additional adjustment cycles, until the first time it is determined in the step 320 after the end of an adjustment cycle that the charging voltage is smaller that the reference voltage V_ref. In this case, it is concluded that the optimum standard value for the capacitance of the capacitor 200 has a value between the standard values for the preceding adjustment cycle and for the current adjustment cycle. If the relevant change in the capacitance between these two adjustment cycles was sufficiently small, the adjustment process can be terminated, because the currently set capacitance of the capacitor 200 agrees sufficiently well with the desired value.

Accordingly, the configuration of the switches connecting the individual capacitors 201, . . . , 207 (FIG. 2) is retained and the capacitor 200 is disconnected from the inventive adjustment circuit 100 and can then, for example, be used in the filter circuit whose time constant it defines. As a result of the inventive adjustment process described here for the capacitor 200, this time constant now agrees as precisely as possible with its desired value, making possible proper operation of the filter circuit.

FIG. 3b shows the process steps of another embodiment of the inventive adjustment method in which the step size by which the standard value for the capacitance of the capacitor 200 is changed between two successive adjustment cycles is chosen in an especially useful way.

First, in step 330, an initial adjustment cycle is carried out in which the minimum possible capacitance value is again set as the standard value for the capacitance of the capacitor 200. Please refer to the flow diagram in FIG. 3a for the individual steps of an adjustment cycle. Then, in step 340, another adjustment cycle follows with a standard value for the capacitance that has been changed, which is to say increased, by a predefinable step size.

Finally, in step 350, a determination is made as to whether the comparison result of the current adjustment cycle 340 is identical to the comparison result of the preceding adjustment cycle 330. If this is the case, the next adjustment cycle 360 is likewise carried out with a standard value for the capacitance that differs from the previously used standard value by the predefinable step size. In other words, the step size is retained for the subsequent adjustment cycle 360.

If the comparison result of the current adjustment cycle 340 is not identical to the comparison result of the preceding adjustment cycle 330, the step size is reduced, in particular cut in half, for the next adjustment cycle 360, which takes place in step 355. In other words, if it is determined in the current adjustment cycle 340 that the charging voltage is smaller than the reference voltage V_ref, yet the charging voltage had still been larger than the reference voltage V_ref in the preceding adjustment cycle 330, then the step size for future adjustment cycles 360 is reduced in order to achieve a closer approach of the standard value for the capacitance to the desired value. In addition, the change in the standard value by the new step size is now carried out in the opposite direction as previously. In the present case, the standard value for the next cycle is then reduced by the new, halved step size, instead of continuing to increase it, and so forth. In this way, the standard value approaches the desired value asymptotically.

Following the reduction of the step size in step 355, step 356 then checks whether the now reduced step size falls below a predefinable threshold value, and the adjustment process is terminated if applicable. For example, the comparison in step 356 can have the result that the step size to be used for future adjustment cycles 360 is smaller than the smallest possible increment for setting the capacitance of the capacitor 200, so that it is not possible to approach the desired value more closely.

If the termination condition just described has not yet been reached, then the next adjustment cycle is carried out in step 360, and then the comparison per step 350 is carried out again, and so forth.

In addition to the termination criterion of the minimum step size to be used, it is also possible to define a maximum number of adjustment cycles to be carried out, which ensures that the process of performing the adjustment does not exceed a predefinable maximum length of time, especially in the event of measurement errors or, for example, because of actual capacitance values that differ excessively from the desired value on account of manufacturing errors.

In addition, it is possible to define in accordance with another embodiment of the inventive method that first two adjustment cycles will be carried out, wherein, for example, the smallest possible capacitance of the capacitor 200 is set for the first adjustment cycle, and wherein, for example, the largest possible capacitance of the capacitor 200 is set for the second adjustment cycle. If both adjustment cycles deliver the same comparison result, it can be assumed that the entire value range of the adjustable capacitance does not contain the desired target value. In this way, it is possible to determine very quickly that adjustment through appropriately setting the capacitance of the capacitor 200 is impossible. In such cases, it is possible if necessary to determine at least the actual capacitance of the capacitor 200 by varying the charging time and the associated “expansion” of the value range of the capacitor.

The inventive method is especially advantageous because, unlike conventional adjustment methods, it requires no complicated and imprecise measurement of pulse durations of a reference signal, instead calling for only a relatively simple voltage comparison by means of the comparator circuit 120. In the best case, only two adjustment steps are needed; this is the case when the step size chosen for the applicable standard values is sufficiently small, and the comparison result in the second adjustment cycle already differs from that of the first comparison cycle.

Typically, more than two comparison cycles should be carried out, with the precise number depending on the desired precision. Since the charging time generally remains constant in the preferred embodiment described above, the maximum duration of the overall adjustment process can be estimated as an integer multiple of the duration of an adjustment cycle multiplied by the maximum number of different standard values to be tested for the capacitance of the capacitor 200.

Even though the versions of the method described above have each used the minimum possible capacitance value of the capacitor 200 as the starting value for the capacitance, it is also possible to start with the maximum possible capacitance value of the capacitor 200 or, for example, to start with a capacitance value located approximately in the middle of the possible value range.

It is also possible to choose a constant step size instead of a variable step size for the change in standard values for the capacitance between successive adjustment cycles. In this case, the achievable precision is limited directly by the constant step size, however.

Moreover, it is also conceivable to perform two or more adjustment passes in which constant step sizes are used in each case. For example, a relatively large step size can be used in a first adjustment pass, in order to obtain a rough approximation for the optimum standard value for the capacitance with few adjustment cycles. In a second adjustment pass, the interval of capacitance values determined in the first adjustment pass can then be further investigated by means of several adjustment cycles with a relatively small, but constant, step size.

Furthermore, in another embodiment of the inventive method, provision is made for the step size to be selected as a function of the number of comparison cycles or adjustment cycles already performed.

In another, embodiment of the inventive method, provision is made that, alternatively or in addition, the charging time for a next adjustment cycle is selected as a function of the comparison result of at least one preceding adjustment cycle.

Especially in the case where the capacitor 200 is charged by means of a constant current, this variant of the invention permits a simple expansion of the available measurement range. For example, halving the capacitance value set for the capacitor 200 can be simulated by doubling the charging time compared to its nominal value, and so forth. While it may not be possible under certain circumstances to make an actual adjustment of the capacitor 200 in the form that appropriate individual capacitors 201, . . . , 207 are switched in, and thus the target value for the capacitance is set, because the expanded value range that is investigated is a result of the variation of the charging time rather than resulting from actual setting of a standard value for the capacitance, the actual capacitance of the capacitor 200 can in any case be determined in the value range expanded by variation of the charging time and, if applicable, can be made available as calibration data to a filter circuit (not shown) using the capacitor 200.

As a result of the inventive adjustment method, use of a relatively simple adjustment circuit is possible, and in particular, the measurement of the pulse duration of a reference signal known from the prior art can be dispensed with. Moreover, the inventive circuit 100 requires far less chip area than conventional adjustment circuits, in which the capacitance of the capacitive element is enlarged in a targeted way in order to increase the time constant defined thereby, and thus the pulse duration to be measured, so that a high frequency clock signal used to measure the pulse duration need only have a reduced clock frequency corresponding to the increase in the time constant in order to provide the same precision. In contrast to the conventional adjustment circuits and methods, the precision of the inventive method is determined by the increment of the capacitance values of the capacitor 200, so that it is not necessary to provide especially large capacitance values, but rather a smaller increment of the adjustable capacitance values. In all, the invention makes it possible to reduce the chip area requirement by approximately 75% for the same precision.

Because of its small chip area requirements, the inventive circuit 100 integrates especially well, and the individual capacitors of the capacitive element 200 may be designed as MIM (metal insulator metal) capacitors, for example.

In another embodiment of the present invention, provision is made that, in place of the change in standard value for the capacitance of the capacitor 200, refer to FIG. 1, a change is undertaken in the standard value for the resistance of a resistive element (not shown) that, together with the capacitive element 200, forms the RC element to be adjusted. The inventive method can be applied in analogous fashion, and a correspondingly tunable resistive element can be designed, for example, as a configurable resistance matrix with a plurality of individual ohmic resistances, which can be connected to one another in analogous fashion to the individual capacitors depicted in FIG. 2, in order to realize one different equivalent resistance in each case. The resistive element can in this case be integrated in the charging circuit 110 or be designed to be capable of integration therein such that it directly determines the charging current for charging the capacitor 200 through its resistance, so that its resistance value helps to determine the charging time investigated in accordance with the invention. In general, any other type of preferably integratable controllable resistances may also be used alternatively or in addition to the use of switchable ohmic resistances.

Alternatively to the above-described integration of the resistive element into the charging circuit 110, the resistive element can also be provided in place of the charging circuit depicted in FIG. 1, or can itself constitute the charging circuit 110. In this case, the resistive element can be connected through the switch 160 to the capacitor 200, with which it forms the RC element to be adjusted. A reference voltage source can be connected to the terminal of the resistive element that is not connected to the switch 160, in order to make possible an RC charging process for the RC element. As already described, in such a charging of the capacitor 200 it is advantageous to choose the charging time such that it is less than the time constant defined by the RC element in order to use a primarily linear region of the time behavior of the charging current and the charging voltage for the inventive adjustment, rather than the asymptotic region at charging times representing a multiple of the time constant.

In addition, when changing the standard value for the resistance, as well as when changing the standard values for capacitance and resistance, the charging time can also be changed in order to increase the value range of the components involved in the manner described above.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for adjusting an RC element with a capacitive element having an adjustable capacitance and/or a resistive element with an adjustable resistance, wherein multiple adjustment cycles are performed, each adjustment cycle comprising:
setting a standard value for the capacitance of the capacitive element and/or for the resistance of the resistive element;
charging the capacitive element for a predefinable charging time;
comparing a charging voltage to which the capacitive element has been charged during the charging time with a reference voltage;
obtaining a comparison result that indicates whether the charging voltage is larger than the reference voltage or vice versa; and
selecting a standard value for the capacitance and/or the resistance and/or the charging time for a subsequent adjustment cycle as a function of the comparison result of at least one preceding adjustment cycle.

2. The method according to claim 1, wherein the standard value for the capacitance for the next adjustment cycle is increased/decreased and/or wherein the standard value for the resistance for the next adjustment cycle is increased/decreased if the charging voltage in the preceding adjustment cycle was larger/smaller than the reference voltage.

3. The method according to claim 1, wherein the charging time for the next adjustment cycle is increased/decreased if the charging voltage in the preceding adjustment cycle was larger/smaller than the reference voltage.

4. The method according to claim 1, wherein the capacitive element is charged by a charging circuit having a constant current.

5. The method according to claim 1, wherein the capacitive element is charged by a charging circuit through a dropping resistor and a reference voltage source, wherein the dropping resistor is formed at least partially from the resistive element.

6. The method according to claim 1, wherein a maximum or minimum adjustable capacitance of the capacitive element and/or a maximum or minimum adjustable resistance of the resistive element is chosen as a standard value for a first adjustment cycle.

7. The method according to claim 6, wherein the standard value is changed by a predefinable step size between each set of successive adjustment cycles.

8. The method according to claim 7, wherein the step size is constant.

9. The method according to claim 7, wherein the step size is variable.

10. The method according to claim 9, wherein the step size is chosen as a function of the number of adjustment cycles previously performed.

11. The method according to claim 9, further comprising the steps of:
maintaining a present value of the step size for the next adjustment cycle if the comparison result of the current adjustment cycle is identical to the comparison result of the preceding adjustment cycle;
reducing or halving the present step size for the next adjustment cycle if the comparison result of the current adjustment cycle is not identical to the comparison result of the preceding adjustment cycle; and
ending the adjustment when the step size chosen for the next adjustment cycle drops below a predefined threshold value.

12. The method according to claim 1, wherein the capacitive element is discharged after the comparison step.

13. The method according to claim 1, wherein a charging circuit used to charge the capacitive element is disconnected from the capacitive element before the comparison step.

14. A circuit for adjusting an RC element having a capacitive element with an adjustable capacitance and/or a resistive element with an adjustable resistance, the circuit comprising:
a charging circuit for charging the capacitive element that is connectable at least to a first terminal of the capacitive element;
a comparator circuit having a first input, a second input, and an output, the first input being supplied with a reference potential corresponding to a reference voltage, and the second input being connectable to the first terminal of the capacitive element; and
a control device that is configured to control the circuit by an adjustment process, the adjustment process comprising:
setting a standard value for the capacitance of the capacitive element and/or for the resistance of the resistive element;
charging the capacitive element for a predefinable charging time;
comparing a charging voltage to which the capacitive element has been charged during the charging time with a reference voltage;
obtaining a comparison result that indicates whether the charging voltage is larger than the reference voltage or vice versa; and
selecting a standard value for the capacitance and/or the resistance and/or the charging time for a subsequent adjustment cycle as a function of the comparison result of at least one preceding adjustment cycle.

15. The circuit according to claim 14, wherein the control device has a state machine and/or is designed as a state machine.

16. The circuit according to claim 14, further comprising a discharging circuit for discharging the capacitive element, the discharging circuit being connectable to at least one terminal of the capacitive element.

17. The circuit according to claim 14, further comprising a clock generator circuit for producing a clock signal.

18. The circuit according to claim 14, further comprising a switch for connecting the charging circuit to the capacitive element.

19. The method according to claim 1, wherein the capacitive element is a capacitor.

20. The method according to claim 1, wherein the resistive element is an ohmic resistance element.
